(19) United States
(12) Patent Application Publication
(10) Pub. No.: US 2018/0040580 A1
(43) Pub. Date: Feb. 8, 2018

(54) POWER ELECTRONICS MODULE WITH A SUPPORT WITH A PALLADIUM/OXYGEN DIFFUSION BARRIER LAYER AND A SEMICONDUCTOR ELEMENT CONNECTED THERETO BY MEANS OF SINTERING, AND METHOD FOR PRODUCING SAME

(71) Applicant: HERAEUS DEUTSCHLAND GMBH & CO. KG, Hanau (DE)

(72) Inventors: Frank KRÜGER, Nidderau (DE); Gerald FREISE, Osterwieck (DE)

(73) Assignee: HERAEUS DEUTSCHLAND GMBH & CO. KG, Hanau (DE)

(21) Appl. No.: 15/554,004

(22) PCT Filed: Feb. 24, 2016
(86) PCT No.: PCT/EP2016/053846

§ 371 Date: Aug. 27, 2017

(30) Foreign Application Priority Data
Feb. 26, 2015 (DE) 10 2015 102 759.3

(51) Int. Cl. H01L 23/00; H01L 21/48; H01L 23/14; H01L 23/495

(52) U.S. Cl. CPC H01L 24/32; H01L 23/49582; H01L 21/4821; H01L 23/14; H01L 23/49513; H01L 24/83; H01L 24/27; H01L 24/29; H01L 2224/32245; H01L 2224/32501; H01L 2224/3201; H01L 2224/29139; H01L 2224/27312; H01L 2224/8384; H01L 2224/83192; H01L 2224/83193; H01L 2224/83203; H01L 2224/2732; H01L 2224/27418; H01L 2224/83439; H01L 2224/83464; H01L 2224/83455

(57) ABSTRACT

A power electronics module includes a semiconductor element and a support with a functional surface for indirectly connecting to the semiconductor element. A palladium barrier layer is formed directly or indirectly on the functional surface, and the semiconductor element is directly or indirectly connected to the barrier layer face facing away from the functional surface by a layer of sintering silver paste. A silver layer is can be formed on the barrier layer, and a nickel layer can be formed between the functional surface and the barrier layer.

### BACKGROUND OF THE INVENTION

### 1. Field of the Invention

The invention relates to a power electronics module, having at least one semiconductor element, in particular a power semiconductor element, and a support having at least one functional surface for connection to the semiconductor element. The invention also relates to a method for producing such a power electronics module.

### 2. Discussion of the Related Art

In power electronics, the requirements made of corresponding power electronics modules are constantly increasing. This concerns, inter alia, the continuous use temperatures or peak temperatures to which a power electronics module should be reliably exposed. The connection of semiconductor elements, in particular of power semiconductors, to substrates and/or leadframes and/or DCB is increasingly being carried out with the aid of so-called silver sintering pastes. At elevated temperatures of, for example, above 200° C., the permeability of such silver layers for oxygen is so high that oxidation of the base metallization of the substrates may occur. Substrates are usually produced from copper.

As a consequence of oxidation of the base metallization, the coating and, thus, the semiconductor element may detach from the substrate.

### SUMMARY OF THE INVENTION

The invention is based on the object of specifying a power electronics module developed further in which such undesired detachments of coatings and/or semiconductor elements cannot occur. The invention is furthermore based on the object of specifying a method for producing such a power electronics module.

The invention is based on the concept of specifying a power electronics module comprising at least one semiconductor element, in particular a power semiconductor element. Furthermore, the power electronics module comprises a support having at least one functional surface for indirect connection to the semiconductor element.

According to the invention, a barrier layer composed of palladium is formed directly or indirectly on the functional surface of the support at least in sections. The semiconductor element is connected, by means of a layer composed of a silver sintering paste, directly or indirectly to the side of the barrier layer facing away from the functional surface of the support.

On account of the formation of a barrier layer or intermediate layer composed of palladium, a barrier for oxygen diffusion is formed for the silver. The oxidation of the underlying material of the support is thus prevented. The barrier layer or intermediate layer constitutes a barrier for oxygen permeation or oxygen diffusion through the silver to the metallization of the support. Consequently, the adhesion of the silver sintering paste or silver sintering layer on the support does not decrease during the ageing of the power electronics module. Consequently, detachment of the silver sintering paste or silver sintering layer and thus also detachment of the semiconductor element from the support are prevented.

The barrier layer composed of palladium may have a layer thickness of 0.1 μm-1.0 μm, in particular of 0.3 μm-0.7 μm, in particular of 0.4 μm-0.6 μm.

In one embodiment of the invention, a silver layer, in particular applied electrolytically, may be formed at least in sections between the barrier layer, namely the barrier layer composed of palladium, and the layer composed of a silver sintering paste.

Said silver layer may have a layer thickness of 0.1 μm-5.0 μm, in particular of 0.5 μm-2.0 μm. Preferably, the silver layer with the layer thicknesses mentioned is deposited electrolytically on the barrier layer composed of palladium. The barrier layer composed of palladium is also preferably deposited electrolytically directly or indirectly on the functional surface of the support.

Furthermore, a nickel layer may be formed at least in sections between the functional surface of the support and the barrier layer. The nickel layer may have a layer thickness of 0.025 μm-3.0 μm, in particular of 0.1 μm-2.0 μm.

The support of the power electronics module may also be referred to as a substrate. A so-called leadframe may be involved here, for example.

The support may be formed for example from copper and/or a copper alloy and/or from nickel.

In one particularly preferred embodiment of the invention, a diffusion layer is formed by application of pressure and/or application of heat during the connection of the semiconductor element to the support. A palladium-silver diffusion layer is involved here.

The semiconductor element of the power electronics module according to the invention is applied by means of a silver sintering paste directly or indirectly to the side of the barrier layer facing away from the functional surface of the support. The application or connection of the semiconductor element to the support is carried out in the context of a sintering process. On account of the application of pressure and/or application of heat in the sintering process, a palladium-silver diffusion layer is formed in the power electronics module. In particular, the palladium of the barrier layer diffuses into the silver layer and/or into the layer composed of a silver sintering paste.

The palladium-silver diffusion layer may have a layer thickness of 5 nm-300 nm, in particular of 10 nm-200 nm.

The silver sintering paste is a standard silver sintering paste.

The invention is furthermore based on the concept of specifying a method for producing a power electronics module, in particular for producing a power electronics module according to the invention. The power electronics module to be produced comprises at least one semiconductor element, in particular a power semiconductor element, and a support having at least one functional surface for connection to the semiconductor element.

The method is characterized by the following method steps according to the invention:
a) at least in sections directly or indirectly, in particular electrolytically, coating the functional surface of the support with a barrier layer composed of palladium;
b) applying, at least in sections, a layer composed of a silver sintering paste to a side of the semiconductor element or directly to the barrier layer of the support or indirectly to the barrier layer of the support;
c) connecting the semiconductor element to the support by means of the layer composed of silver sintering paste by application of heat.

In a first step, accordingly, the support, which may also be referred to as a substrate or a leadframe, is coated at least in sections with a barrier layer composed of palladium. The support or the substrate or the leadframe is produced from copper, for example. The barrier layer composed of palladium is applied in particular electrolytically to the support at least in sections. In a further step, a layer composed of silver sintering paste is applied at least in sections either to the semiconductor element or to the support. The layer composed of a silver sintering paste may be applied either to the semiconductor element or to the support for example by means of a stencil printing method or a spraying method or a dispensing method. If the layer composed of a silver sintering paste is applied on the semiconductor element, the layer composed of a silver sintering paste should be applied on that side of the semiconductor element which later is connected to the support.

If the layer composed of a silver sintering paste is applied on the support, the layer composed of a silver sintering paste should be applied directly or indirectly to the barrier layer of the support. The semiconductor element and the support must be positioned with respect to one another in such a way that the semiconductor element can be connected to the barrier layer of the support directly or indirectly by means of the layer composed of silver sintering paste. The semiconductor element is connected to the support by means of the layer composed of silver sintering paste with application of heat being carried out. The connection process may also be referred to as joining the semiconductor element to the support.

In a further embodiment of the method according to the invention, it is conceivable for the barrier layer composed of palladium to be coated with a silver layer at least in sections before connection to the semiconductor element. Preferably, the coating of the barrier layer with a silver layer at least in sections is carried out by electrolytic deposition.

The functional surface of the support may be coated with a nickel layer at least in sections before step a), that is to say before the, in particular electrolytic, coating of the functional surface of the support with a barrier layer composed of palladium. A nickel layer is applied to the support, in particular to the functional surface of the support, primarily if the support consists of copper or a copper alloy.

Application of pressure may be carried out in step c), that is to say during the connection of the semiconductor element to the support.

A palladium-silver diffusion layer is formed by application of pressure and/or application of heat during the connection of the semiconductor element to the support. In other words, during the connection or joining of the semiconductor element to the support on account of the application of pressure and/or application of heat in the power electronics module a palladium-silver diffusion layer is formed. This is effected by the palladium of the barrier layer diffusing into the silver layer or into the layer composed of a silver sintering paste.

On account of such a palladium-silver diffusion layer, this forms an effective barrier for the oxygen permeation or oxygen diffusion through the silver layer or layer of a silver sintering paste to the base metallization of the support. The oxidation of the layers is thereby prevented. The silver sintering layer and hence the semiconductor element adhere on the support during the entire lifetime.

### BRIEF DESCRIPTION OF THE INVENTION

The invention is explained more specifically below with further details on the basis of exemplary embodiments with reference to the accompanying schematic drawings.

In said drawings:

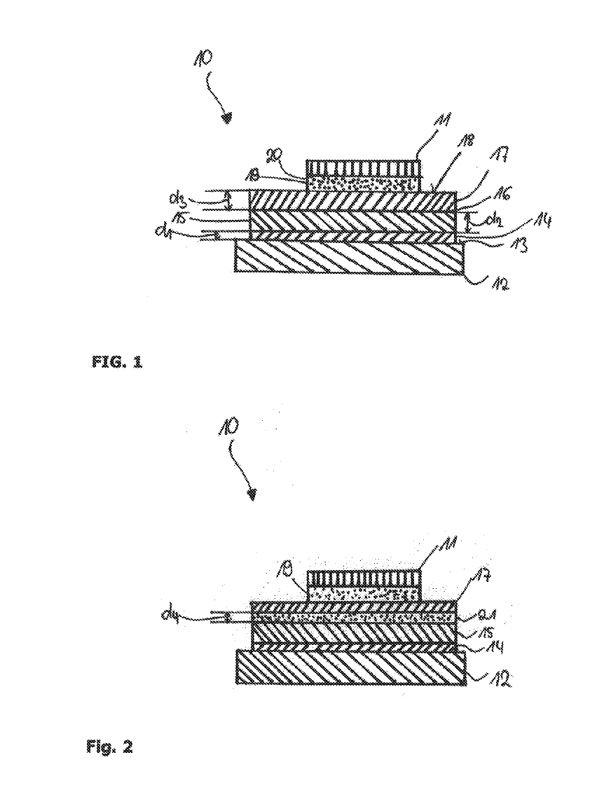

FIG. 1 shows a power electronics module according to the invention in accordance with a first embodiment; and

FIG. 2 shows a power electronics module according to the invention with a palladium-silver diffusion layer having been formed.

The same reference numerals are used hereinafter for identical and identically acting parts.

FIG. 1 illustrates the structure of a power electronics module 10 according to the invention.

The module comprises a semiconductor element 11. Said semiconductor element 11 may be in particular a power semiconductor element. Furthermore, the power electronics module 10 comprises a support 12. The support 12 is for example a leadframe formed from a copper material. The support 12 has a functional surface 13, which serves for indirect connection to the semiconductor element 11.

A nickel layer 14 is applied on the functional surface of the support 12. The layer thickness d1 of the nickel layer 14 may be 0.05 μm-3.0 μm, for example.

A barrier layer 15 composed of palladium is formed at least in sections on the nickel layer 14. In other words, the barrier layer 15 composed of palladium is formed indirectly on the functional surface 13 of the support 12. The barrier layer 15 composed of palladium may have a layer thickness d2 of 0.1 μm-0.5 μm. A silver layer 17, in particular applied electrolytically, is formed at least in sections on the barrier layer 15, namely on the side 16 of the barrier layer 15 facing away from the functional surface 13 of the support 12. The silver layer 17 may have a layer thickness d3 of 0.5 μm-2.0 μm.

A layer 19 composed of a silver sintering paste is formed at least in sections on the side 18 of the silver layer 17 facing away from the functional surface 13 of the support 12 or from the barrier layer 15. The layer 19 composed of a silver sintering paste serves for connecting the semiconductor element 11 to the support 12.

FIG. 1 illustrates the state in which the semiconductor element 11 has already been joined together with the support 12. The layer 19 composed of a silver sintering paste may either be applied on the side 18 of the silver layer 17 before the joining together process, such that the semiconductor element 11 is attached to the layer 19 composed of silver sintering paste by the side 20 facing the support 12.

Alternatively, it may be provided that the layer 19 composed of a silver sintering paste is firstly applied on the side 20 of the semiconductor element 11. This is followed by the semiconductor element 11 provided with a silver sintering paste being joined together indirectly with the support 12.

As can be gathered from FIG. 1, the layer 19 composed of a silver sintering paste is indirectly connected to the side 16 of the barrier layer 15 facing away from the functional surface 13 of the support 12.

A sintering process is carried out in order to connect the semiconductor element 11 to the support 12 by means of the layer 19 composed of silver sintering paste. This is accompanied by application of pressure and/or application of heat. That is to say that while at least slight pressure is applied to the semiconductor element 11 and to the support 12 or to the layers 14, 15, 17 and 19 situated between the support material 12 and the semiconductor element 11, said pressure serving for adhering the semiconductor element 11 on the underlying layers, application of heat is carried out at the same time.

As is illustrated in FIG. 2, the palladium of the barrier layer 15 diffuses into the silver of the silver layer 17, such that a palladium-silver diffusion layer 21 is formed. Said palladium-silver diffusion layer 21 forms a barrier for the oxygen permeation or oxygen diffusion through the silver sintering paste layer 19 and silver layer 17 to the metal of the support 12. Oxidation of the support metallization is thus prevented. The silver layer 17 or the layer 19 composed of a silver sintering paste consequently does not detach from the support 12 or the nickel layer 14 even at relatively high temperatures to which the power electronics module 10 is exposed.

The layer thickness d4 of the palladium-silver diffusion layer 21 may be 5 nm-300 nm, in particular 10 nm-200 nm.

Tests have shown, for example, that the silver layer 17 or the layer composed of silver sintering paste 19 is not detached from the barrier layer 15 even after being subjected to a temperature of 245° C. over 690 hours.

It should be pointed out at this juncture that all elements and components described above in association with the embodiments in accordance with FIGS. 1 and 2, as considered by themselves or in any combination, in particular the details illustrated in the drawings, are claimed as essential to the invention.

### LIST OF REFERENCE SIGNS

10 Power electronics module
11 Semiconductor element
12 Support
13 Functional surface
14 Nickel layer
15 Barrier layer
16 Side of barrier layer
17 Silver layer
18 Side of silver layer
19 Layer composed of a silver sintering paste
20 Side of semiconductor element
21 Palladium-silver diffusion layer
d1 Layer thickness of nickel layer
d2 Layer thickness of barrier layer
d3 Layer thickness of silver
d4 Layer thickness of palladium-silver diffusion layer

1. A power electronics module comprising:
a semiconductor element;
s support comprising a functional surface for indirect connection to the semiconductor element;
a barrier layer comprising palladium; and
a second layer comprising a silver sintering paste;
wherein the barrier layer being formed on the functional surface directly or indirectly at least in sections of the functional surface;
wherein the semiconductor element is connected by the second layer directly or indirectly to a first side of the harder layer, the first side facing away from the functional surface.

2. The power electronics module as claimed in claim 1, wherein the barrier layer comprises a layer thickness of 0.1 μm-1.0 μm, 0.3 μm-0.7 μm, or 0.4 μm-0.6 μm.

3. The power electronics module as claimed in claim 1,
further comprising a third layer consisting of silver,
wherein the third layer is electrolytically applied at least in sections between the barrier layer and the second layer.

4. The power electronics module as claimed in claim 3, wherein the third layer comprises a layer thickness of 0.1 μm-5.0 μm or 0.5 μm-2.0 μm.

5. The power electronics module as claimed in claim 1, further comprising a nickel layer is formed at least in sections between the functional surface and the barrier layer.

6. The power electronics module as claimed in claim 5, the nickel layer comprises a layer thickness of 0.025 μm-3.0 μm or 0.1 μm-2.0 μm.

7. The power electronics module as claimed in claim 1, wherein the support is formed from copper, a copper alloy, or nickel.

8. The power electronics module as claimed in claim 1,
further comprising a palladium-silver diffusion layer,
wherein the palladium-silver diffusion layer is formed by application of pressure or application of heat during when connecting the semiconductor element to the support.

9. The power electronics module as claimed in claim 8, wherein the palladium-silver diffusion layer comprises a layer thickness of 5 nm-300 nm or 10 nm-200 nm.

10. A method for producing a power electronics module,
the power electronics module comprising:
a semiconductor element;
a support comprising a functional surface for indirect connection to the semiconductor element;
a barrier layer comprising palladium; and
a second layer comprising a silver sintering paste;
wherein the barrier layer being, formed on the functional surface directly or indirectly at least in sections of the functional surface;
wherein the semiconductor element is connected by the second layer directly or indirectly to a first side of the barrier layer; the first side facing away from the functional surface;
the method comprising the steps of
(a) at least in sections directly or indirectly electrolytically coating the functional surface of the support with the barrier layer,
(b) applying a layer composed of the silver sintering paste to a side of the semiconductor element or directly to the barrier layer of the support or indirectly to the barrier layer; and
(c) connecting the semiconductor element to the support by means of the layer composed of silver sintering paste by application of heat.

11. The method as claimed in claim 10, wherein the barrier layer is coated with a silver layer at least in sections when connecting to the semiconductor element.

12. The method as claimed in claim 10, wherein before step (a) the functional surface of the support is coated with a nickel layer at least in sections.

13. The method as claimed in claim 10, wherein step (c) is performed by application

14. The method as claimed in claim 10, wherein a palladium-silver diffusion layer is diffused by application of pressure or application of heat during when connecting of the semiconductor element.
